(19) United States
(12) Patent Application Publication
(10) Pub. No.: US 2013/0240797 A1
(43) Pub. Date: Sep. 19, 2013

(54) COMPOUND SEMICONDUCTOR

(71) Applicants: Akihiro Nagoya, Aichi-gun (JP); Ryoji Asahi, Miyoshi-shi (JP); Tatsuo Fukano, Nagoya-shi (JP); Hirofumi Hazama, Nagoya-shi (JP); Yumi Saiki, Nisshin-shi (JP); Toshihisa Shimo, Kariya-shi (JP); Nobuhiro Goda, Kariya-shi (JP); Satoshi Nakagawa, Kariya-shi (JP)

(72) Inventors: Akihiro Nagoya, Aichi-gun (JP); Ryoji Asahi, Miyoshi-shi (JP); Tatsuo Fukano, Nagoya-shi (JP); Hirofumi Hazama, Nagoya-shi (JP); Yumi Saiki, Nisshin-shi (JP); Toshihisa Shimo, Kariya-shi (JP); Nobuhiro Goda, Kariya-shi (JP); Satoshi Nakagawa, Kariya-shi (JP)

(73) Assignee: KABUSHIKI KAISHA TOYOTA CHUO KENKYUSHO, Aichi-gun, Aichi-ken (JP)

(21) Appl. No.: 13/988,456

(22) PCT Filed: Nov. 29, 2011
(86) PCT No.: PCT/JP2011/077458

§ 371 Date: May 20, 2013

(30) Foreign Application Priority Data
Dec. 6, 2010 (JP) 2010 271947
Nov. 2, 2011 (JP) 2011 241670

(51) Int. Cl. H01L 31/032

(52) U.S. Cl. CPC H01L 31/032
USPC 252/501.1

(57) ABSTRACT

A compound semiconductor contains main constituent elements all of which satisfy the relationship (Cu_{1-w}A_{w})₂₍₁₊ₐ₎(Zn₁₋ₓBₓ)_{1+b}(Sn_{1-y}C_{y})_{1+c}(Sn_{1-z}Se_{z})_{4(1+d)} and having a CZTSX-based compound as a main phase, where −0.3≦a≦0.3, −0.3 ≦b≦0.3, −0.3≦c≦0.3, −0.3≦d≦0.3, 0≦w<0.5, 0≦x <0.5, 0≦y<0.5, 0≦z<1.0 and 0<x+y+z+w. The element A is at least one element selected from the group consisting of group Ia elements, group IIa elements, group Ib elements (excluding Cu) and group IIb elements. The element B is at least one element selected from the group consisting of group IIa elements and group Ib elements. The element C is at least one element selected from the group consisting of Zn, group IIIb elements and group IVb elements. A compound in which x=y=z=0 and the element A is Ag, and a compound in which x=y=w=0 are_excluded from the formula.

### FIELD OF THE INVENTION

The present invention relates to a compound semiconductor and, more specifically, to a compound semiconductor having a CZTSX-based compound phase as the main phase formed by substituting one or more sites of a CZTS-based compound with a dopant X.

### BACKGROUND OF THE INVENTION

A photovoltaic device refers to a device capable of converting (photovoltaic conversion) the photon energy into an electric signal through some physical phenomenon. A solar cell is a type of photovoltaic device which can convert the energy of the solar illumination into electric energy efficiently.

As semiconductors for use in solar cells, there are known monocrystal Si, polycrystal Si, amorphous Si, GaAs, InP, CdTe, CuIn₁₋ₓGaₓSe₂ (CIGS) and Cu₂ZnSnS₄ (CZTS).

Among them, the chalcogenide-based compounds typified by CIGS and CZTS can each be formed into a cost-advantageous thin film due to the large light absorption coefficient thereof. Especially a solar cell in which CIGS is used in a light absorbing layer has high conversion efficiency among thin-film solar cells, and its conversion efficiency is higher than that of solar cells including polycrystal Si. However, CIGS has a problem that it contains an environmental-burden element and a rare element.

Meanwhile, CZTS has a band gap energy (1.4 to 1.5 eV) suitable for solar cells and contains no environmental-burden element and no rare element.

Various proposals have been made for a photovoltaic conversion material from which a thin film can be made.

For example, Non-Patent Document 1 discloses a solar cell including CIGS and having photovoltaic conversion efficiency of 19.5%.

Non-Patent Document 2 discloses a solar cell including CZTS and having photovoltaic conversion efficiency of 6.7%.

Non-Patent Document 3 discloses a solar cell including Cu₂ZnSnSe₄ (CZTSe) and having photovoltaic conversion efficiency of 2.16%.

Non-Patent Document 4 discloses a photovoltaic conversion material represented by Cu₂Zn₁₋ₓCdₓSn (Se_{1y}S_{y})₄. In this formula, 0≦x≦1.0 and 0≦y≦1.0.

Non-Patent Document 12 discloses a material represented by Cu₂ZnSn(Se₁₋ₓSₓ)₄ and having photovoltaic conversion efficiency of 9.6%.

FIG. 10 of Non-Patent Document 11 shows that, when the band gap of a solar cell material is 1.2 to 1.6 eV, supposing various weather conditions, high photovoltaic conversion efficiency is obtained theoretically.

As for the band gap of CZTSe, Non-Patent Document 4 teaches that it is 0.85 eV and Non-Patent Document 5 teaches that it is 1.02 eV. Meanwhile, Non-Patent Documents 6 and 7 teach that the band gap of CZTSe is 1.44 eV. Non-Patent Document 14 teaches that the band gap of CZTSe is about 1 eV and that the band gap is measured as 1.5 eV due to the precipitation of ZnSe as a heterogeneous phase.

Non-Patent Document 15 calculates the band gap of CZTS as 1.50 eV and the band gap of CZTSe as 0.96 eV theoretically.

Non-Patent Document 8 calculates the band gap of CZTS as 1.2 eV and the band gap of CZTSe as 0.8 eV by rough approximation. The accuracy is evaluated as ±0.4 eV.

Further, Non-Patent Documents 9, 10 and 13 teach theoretical calculation methods of the band gap.

Non-Patent Document 16 teaches that

(a) when a Cu/Sn/ZnS precursor is sulfurized at 530° C., a CZTS light absorbing layer having a Cu/(Zn+Sn) ratio of 0.99, a Zn/Sn ratio of 1.01, an S/metal ratio of 1.07 and conversion efficiency of 1.08% is obtained,
(b) when a multi-periods precursor obtained by stacking 5 cycles of Cu/SnS₂/ZnS is sulfurized, a CZTS light absorbing layer having a Cu/(Zn+Sn) ratio of 0.73, a Zn/Sn ratio of 1.7, an S/metal ratio of 1.1 and conversion efficiency of 3.93% is obtained, and
(c) when a precursor manufactured by simultaneous sputtering is sulfurized, a CZTS light absorbing layer having a Cu/(Zn+Sn) ratio of 0.87, a Zn/Sn ratio of 1.15, an S/metal ratio of 1.18 and conversion efficiency of 5.74% is obtained.

Non-Patent Document 2 and Non-Patent Document 16 teach that when CZTS is formed on Mo-coated soda lime glass (SLG) and washed with ion exchange water, a CZTS light absorbing layer having a Cu/(Zn+Sn) ratio of up to 0.85, a Zn/Sn ratio of up to 1.25, an S/(Cu+Zn+Sn) ratio of up to 1.10 and conversion efficiency of 6.77% is obtained.

Non-Patent Document 17 discloses stannite type composite sulfide A^{I}₂—Zn—A^{IV}—S₄ (A^{I}=Cu and Ag; A^{IV}=Sn and Ge) which is used as a photocatalyst and not a material used in the light absorbing layer of a photoelectric device.

Further, Non-Patent Document 18 discloses the composition of the metal components in a CZTS-based compound. This document teaches that when the Cu/(Zn+Sn) ratio is 0.75 to 1.0 and the Zn/Sn ratio is 1.0 to 1.3, conversion efficiency of not less than 1% is obtained.

CZTS is a cheap and abundant material having an ideal band gap. However, CZTS has lower photovoltaic conversion efficiency than GIGS.

To solve this problem, it is proposed to dope CZTS with Se. However, even Se-doped CZTS has lower photovoltaic conversion efficiency than GIGS.

### CITATION LIST

### Non-Patent Document

[Non-Patent Document 1] R. N. Bhattacharya, Appl. Phys. Lett. 89, 253503 (2006)
[Non-Patent Document 2] H. Katagiri, Appl. Phys. Exp. 1, 041201 (2008)
[Non-Patent Document 3] Mellikov E, Solar Energy Mater. Solar Cells 93, 65 (2009)
[Non-Patent Document 4] Altosaar M, Phys. Stat. Sol. (a) 205, 167 (2008)
[Non-Patent Document 5] M. Grossberg, Thin Solid Films In Press, Corrected Proof, available online November 2008
[Non-Patent Document 6] Babu G S, J. Phys. D: Appl. Phys. 41, 205305 (2008)
[Non-Patent Document 7] Matsushita H, J. Cryst. Growth 208, 416 (2000)
[Non-Patent Document 8] J. M. Raulot, J. Phys. Chem, Solids 66, 2019 (2005)
[Non-Patent Document 9] J. Paier et al., Phys. Rev. B 78, 121201 (2008)
[Non-Patent Document 10] J. Paier et al., Phys. Rev. B 79, 115126 (2009)
[Non-Patent Document 11] J. J. Loferski, J. Appl. Phys. 27, 777 (1956)
[Non-Patent Document 12] Teodor K, Adv. Mater. 22, E156 (2010)
[Non-Patent Document 13] NagoyaA, Phys. Rev. B81, 113203 (2010)
[Non-Patent Document 14] Ahn S, Appl. Phys. Lett. 97, 021905 (2010)
[Non-Patent Document 15] Chen S, Appl. Phys. Lett. 94, 041903 (2009)
[Non-Patent Document 16] H. Katagiri et al., Thin Solid Films 517 (2009)2455-2460
[Non-Patent Document 17] I. Tsuji et al., Chem. Mater., Vol. 22, No. 4, (2010)1402-1409
[Non-Patent Document 18] Proceedings for Sixth “Jisedai no Taiyoko Hatsuden System (Next-Generation Solar Cell Power Generation System)” Symposium, p26

### SUMMARY OF THE INVENTION

It is an object of the present invention to provide a novel compound semiconductor which includes a CZTS-based compound as a base material, is inexpensive and has relatively high photovoltaic conversion efficiency.

To attain the above object, the compound semiconductor of the present invention needs to have the following constitution.

(1) The compound semiconductor contains main constituent elements (Cu, Zn, Sn, S, Se, element A, element B and element C) and inevitable impurities, and the main constituent elements satisfy the following relationship (1).

(Cu_{1-w}A_{w})₂₍₁₊ₐ₎(Zn₁₋ₓBₓ)_{1+b}(Sn_{1-y}C_{y})_{1+c}(S_{1-z}Se_{z})_{4(1+d)} (1)

where −0.3≦a≦0.3, −0.3≦b≦0.3, −0.3≦c≦0.3, −0.3≦d≦0.3, 0≦w<0.5, 0≦x<0.5, 0≦y<0.5, 0≦z≦1.0 and 0<x+y+z+w.

The element A is at least one element selected from the group consisting of group Ia elements, group IIa elements, group Ib elements (excluding Cu) and group IIb elements.

The element B is at least one element selected from the group consisting of group IIa elements and group Ib elements.

The element C is at least one element selected from the group consisting of Zn, group 111b elements and group IVb elements.

A compound in which x=y=z=0 and the element A is Ag, and a compound in which x=y=w=0 are excluded from the formula (1).

### (2) The Compound Semiconductor has a CZTSX-Based Compound Phase as a Main Phase.

To obtain high photovoltaic conversion efficiency, the band gap Eg needs to be in a suitable range and the light absorption coefficient α needs to be high. When at least one site out of the Cu site, Zn site, Sn site and S site of the CZTS-based compound is substituted by a specific element, the light absorption coefficient α increases or the band gap Eg increases.

A dopant having the function of increasing the light absorption coefficient α tends to reduce the band gap Eg. Therefore, when a dopant having the function of increasing the light absorption coefficient α is added alone, the band gap Eg goes out of the suitable range and the photovoltaic conversion efficiency may be lowered.

In contrast to this, when a dopant having the function of increasing the light absorption coefficient α and reducing the band gap Eg and a dopant having the function of increasing the band gap Eg are added at the same time, the light absorption coefficient α increases while the band gap Eg is kept in a suitable range.

### BRIEF DESCRIPTION OF THE DRAWINGS

FIG. 1A is a diagram showing formation energy when the Cu site, Zn site or Sn site of CZTS with excessive Cu is substituted by each of various elements;

FIG. 1B is a diagram showing formation energy when the Cu site, Zn site or Sn site of CZTS poor in Cu is substituted by each of the elements;

FIG. 2A is a diagram showing formation energy when the Cu site, Zn site or Sn site of CZTS with excessive Cu is substituted by each of various elements;

FIG. 2B is a diagram showing formation energy when the Cu site, Zn site or Sn site of CZTS poor in Cu is substituted by each of the elements;

FIG. 3A is a diagram showing formation energy when the Cu site, Zn site or Sn site of CZTS with excessive Cu is substituted by each of various elements;

FIG. 3B is a diagram showing formation energy when the Cu site, Zn site or Sn site of CZTS poor in Cu is substituted by each of the elements;

FIG. 4A is a diagram showing the imaginary part of the dielectric constant of CZTS obtained by calculation;

FIG. 4B is a diagram showing the imaginary part of the dielectric constant of CZTSe obtained by calculation;

FIG. 5 is the X-ray diffraction pattern of sample 1 (Cu₂ZnSnS₄);

FIG. 6 is a diagram showing the absorption coefficient α′ of sample 1 (Cu₂ZnSnS₄);

FIG. 7 is a diagram showing the experimental value and the calculated value by electronic structure calculation of the dielectric constant s of sample 1 (Cu₂ZnSnS₄);

FIG. 8 is a diagram showing the influence upon I-V characteristics of the addition amount of Ag;

FIG. 9 is a diagram showing the influence on V_{oc} of the addition amount of Ag;

FIG. 10A is the X-ray diffraction pattern of Ag_{a′}Zn_{b′}Sn_{c′}S_{d′};

FIG. 10B is the X-ray diffraction pattern of (Cu_{0.75}Ag_{0.25})_{a′}Zn_{b′}Sn_{c′}S_{d′};

FIG. 11A shows the X-ray diffraction pattern of (Cu_{0.95}Ag_{0.05})_{a′}Zn_{b′}Sn_{c′}S_{d′}; and

FIG. 11B is the X-ray diffraction pattern of Cu_{a′}Zn_{b′}Sn_{c′}S_{d′}.

### DETAILED DESCRIPTION OF THE PREFERRED EMBODIMENTS

A preferred embodiment of the present invention will be described in detail hereinunder.

### 1. Compound Semiconductor

The compound semiconductor of the present invention has the following constitution.

(1) The compound semiconductor contains main constituent elements (Cu, Zn, Sn, S, Se, element A, element B and element C) and inevitable impurities, and the main constituent elements satisfy the following relationship (1).

(Cu_{1-w}A_{w})₂₍₁₊ₐ₎(Zn₁₋ₓBₓ)_{1+b}(Sn_{1-y}C_{y})_{1+c}(S_{1-z}Se_{z})_{4(1+d)} (1)

where −0.3≦a≦0.3, −0.3≦b≦0.3, −0.3≦c≦0.3, −0.3≦d≦0.3, 0≦w<0.5, 0≦x<0.5, 0≦y<0.5, 0≦z≦1.0 and 0<x+y+z+w.

The element A is at least one element selected from the group consisting of group Ia elements, group IIa elements, group Ib elements (excluding Cu) and group IIb elements.

The element B is at least one element selected from the group consisting of group IIa elements and group Ib elements.

The element C is at least one element selected from the group consisting of Zn, group IIb elements and group IVb elements.

A compound in which x=y=z=0 and the element A is Ag, and a compound in which x=y=w=0 are excluded from the formula (1).

(2) The compound semiconductor has a CZTSX-based compound phase as a main phase.

### [1.1. Composition]

[1.1.1. a, b, c, d]

The compound semiconductor of the present invention has, as a main phase, a compound (this is called “CZTSX-based compound” in the present invention) which is formed by substituting at least one of the Cu site, Zn site, Sn site and S site of a so-called CZTS-based compound, which contains a phase represented by the general formula Cu₂₍₁₊ₐ₎Zn_{1+b}Sn_{1+c}S_{4(1+d)}, by a specific element X and having a predetermined crystal structure. The term “CZTSX-based compound phase as a main phase” means that the strongest peak of an XRD pattern is a diffraction peak derived from the CZTSX-based compound.

The composition of the CZTS-based compound which is the base material of the compound semiconductor of the present invention is not particularly limited and may be arbitrarily selected according to purpose. That is, in the present invention, the term “CZTS-based compound” means all compounds that contain Cu, Zn, Sn and S as the main components and function as a p-type semiconductor.

When “a” to “d” are within predetermined ranges and a phase having a predetermined crystal structure is contained in the CZTS-based compound represented by the general formula Cu₂₍₁₊ₐ₎Zn_{1+b}Sn_{1+c}S_{4(1+d)}, the CZTS-based compound functions as a p-type semiconductor. The same can be said of the CZTSX-based compound.

It is known that a CZTS-based compound (2a<b+c) poor in Cu has higher conversion efficiency than a CZTS-based compound (2a=b+c) having stoichiometric composition.

In contrast to this, if the amount of the Cu site atom of the CZTSX-based compound is larger than its stoichiometric amount, when the type and amount of the dopant X are optimized, high conversion efficiency may be obtained. However, when the amount of the Cu site atom is too small or when it is too large, a heterogeneous phase tends to be formed. Particularly when the amount of the Cu site atom is large, a heterogeneous phase is more easily formed than when the amount of the Cu site atom is small.

Therefore, “a” needs to be −0.3 or more. “a” is preferably −0.2 or more. “a” needs to be 0.3 or less. “a” is preferably 0.1 or less.

Further, it is known that a CZTS-based compound (b>c) with excessive Zn has higher conversion efficiency than a CZTS-based compound (b=c) having stoichiometric composition.

In contrast to this, if the amount of the Zn site atom of the CZTSX-based compound is smaller than its stoichiometric amount, when the type and amount of the dopant X are optimized, high conversion efficiency may be obtained. However, when the amount of the Zn site atom is too small or when it is too large, a heterogeneous phase tends to be formed. Particularly when the amount of the Zn site atom is large, a heterogeneous phase is more easily formed than when the amount of the Zn site atom is small.

Therefore, “b” needs to be −0.3 or more. “b” is preferably −0.2 or more. “b” needs to be 0.3 or less. “b” is preferably 0.1 or less.

Similarly, it is known that a CZTS-based compound (b>c) poor in Sn has higher conversion efficiency than a CZTS-based compound (b=c) having stoichiometric composition.

In contrast to this, if the amount of the Sn site atom of the CZTSX-based compound is larger than its stoichiometric amount, when the type and amount of the dopant X are optimized, high conversion efficiency may be obtained. However, when the amount of the Sn site atom is too small or when it is too large, a heterogeneous phase tends to be formed. Particularly when the amount of the Sn site atom is large, a heterogeneous phase is more easily formed than when the amount of the Sn site atom is small.

Therefore, “c” needs to be −0.3 or more. “c” is preferably −0.2 or more. “c” needs to be 0.3 or less. “c” is preferably 0.1 or less.

Further, it is known that a CZTS-based compound (2a+b+c<4d) with excessive S has higher conversion efficiency than a CZTS-based compound (2a+b+c=4d) having stoichiometric composition.

In contrast to this, if the amount of the S site atom of the CZTSX-based compound is smaller than its stoichiometric amount, when the type and amount of the dopant X are optimized, high conversion efficiency may be obtained. However, when the amount of the S site atom is too small or when it is too large, a heterogeneous phase tends to be formed. Particularly when the amount of the S site atom is large, a heterogeneous phase is more easily formed than when the amount of the S site atom is small.

Therefore, “d” needs to be −0.3 or more. “d” is preferably −0.2 or more. “d” needs to be 0.3 or less. “d” is preferably 0.1 or less.

[1.1.2. x, y, z, w]

In the formula (1), “w” denotes the substitution amount of the Cu site by the element A. The element A has the function of increasing or reducing the light absorption coefficient α, or increasing or reducing the band gap Eg according to its type. This effect is obtained not only by doping the Cu site by the element A but also by doping another site by another element. Therefore, “w” should be 0 or more. “w” is preferably 0.001 or more.

Meanwhile, when the substitution amount of the element A becomes excessive, a heterogeneous phase is formed and conversion efficiency decreases. Therefore, “w” needs to be less than 0.50. “w” is preferably 0.20 or less, more preferably 0.14 or less.

In the formula (1), “x” denotes the substitution amount of the Zn site by the element B. The element B has the function of increasing or reducing the light absorption coefficient α, or increasing or reducing the band gap Eg according to its type. This effect is obtained not only by doping the Zn site by the element B but also by doping another site by another element. Therefore, “x” should be 0 or more. “x” is preferably 0.001 or more.

Meanwhile, when the substitution amount of the element B becomes excessive, a heterogeneous phase is formed and conversion efficiency decreases. Therefore, “x” needs to be less than 0.50. “x” is preferably 0.20 or less, more preferably 0.10 or less.

In the formula (1), “y” denotes the substitution amount of the Sn site by the element C. The element C has the function of increasing or reducing the light absorption coefficient α, or increasing or reducing the band gap Eg according to its type. This effect is obtained not only by doping the Sn site by the element C but also by doping another site by another element. Therefore, “y” should be 0 or more. “y” is preferably 0.001 or more.

Meanwhile, when the substitution amount of the element C becomes excessive, a heterogeneous phase is formed and conversion efficiency decreases. Therefore, “y” needs to be less than 0.50. “y” is preferably 0.20 or less, more preferably 0.09 or less.

In the formula (1), “z” denotes the substitution amount of the S site by Se. Se has the function of increasing the light absorption coefficient α and reducing the band gap Eg. This effect is obtained not only by doping the S site by Se but also by doping another site by another element. Therefore, “z” should be 0 or more. “z” is preferably 0.001 or more.

Even when the substitution amount of Se becomes excessive, a heterogeneous phase is not formed. Therefore, “z” should be 1.0 or less. However, when the substitution amount of Se becomes excessive, the band gap becomes too small. Therefore, “z” is preferably 0.50 or less. “z” is more preferably 0.25 or less.

In the formula (1), “0<x+y+z+w” indicates that at least one site selected from the group consisting of the Cu site, the Zn site, the Sn site and the S site is substituted by a specific element X. Substitutional doping With the element X may be single substitutional doping which is carried out with one element at one site or multiple substitutional doping which is carried out with two or more elements and/or at two or more sites.

In general, a dopant having the function of increasing the light absorption coefficient α has the function of reducing the band gap Eg at the same time inmost cases. Therefore, when a dopant having the function of increasing the light absorption coefficient α and also reducing the band gap Eg and a dopant having the function of increasing the band gap Eg are used in combination to carry out multiple substitutional doping, the light absorption coefficient α can be increased while the band gap Eg is kept in a suitable range.

The term “a compound in which x=y=z=0 and the element A is Ag is excluded from the formula (1)” means that a composition represented by the general formula (Cu_{1-w}Ag_{w})₂₍₁₊ₐ₎Zn_{1+b}Sn_{1+b}Sn_{1+c}S_{4(1+d)} is excluded from the formula (1).

Further, the term “a compound in which x=y=w=0 is excluded from the formula (1)” means that a composition represented by the general formula Cu₂₍₁₊ₐ₎Zn_{1+b}Sn_{1+c}(S_{1-z}Se_{z})_{4(1+d)} is excluded from the formula (1).

### [1.1.3. A, B, C]

The element A is an element substituting the Cu site. Specifically, the element A is at least one element selected from the group consisting of the group Ia elements (Li, Na, K, Rb, Cs, Fr), the group IIa elements (Be, Mg, Ca, Sr, Ba, Ra), the group Ib elements excluding Cu (Ag, Au) and the group IIb elements (Zn, Cd, Hg).

The element B is an element substituting the Zn site. Specifically, the element B is at least one element selected from the group consisting of the group IIa elements (Be, Mg, Ca, Sr, Ba, Ra) and the group Ib elements (Cu, Ag, Au).

The element C is an element substituting the Sn site. Specifically, the element C is at least one element selected from the group consisting of Zn, the group 111b elements (B, Al, Ga, In, Ti) and the group IVb elements (C, Si, Ge, Sn, Pb).

The elements A, B and C have the function of increasing or reducing the light absorption coefficient α, or increasing or reducing the band gap Eg according to their types. Therefore, when a combination of the elements A, B and C and the addition amounts of the elements A to C and Se are optimized, the light absorption coefficient α can be increased and/or the band gap Eg can be kept in a suitable range.

The CZTSX-based compound is preferably such that the element A is at least one element selected from the group consisting of Li, Na, K, Mg, Ca, Sr, Ag, Cd and Zn, the element B is at least one element selected from the group consisting of Mg, Ca, Sr and Cu, and the element C is at least one element selected from the group consisting of Ge, Al and Ga.

When the above elements are selected as the elements A, B and C, it is easy to increase the light absorption coefficient α and/or keep the band gap Eg at a suitable range.

Out of these, elements except for K, Mg, Ca and Sr can substitute corresponding predetermined sites relatively easily.

Meanwhile, K, Mg, Ca and Sr may hardly enter the corresponding sites by single substitutional doping. However, when multiple substitutional doping is carried out by combining an element such as K with another element, it is possible to substitute the corresponding site by an element such as K relatively easily.

The CZTSX-based compound is particularly preferably such that the element A is at least one element selected from the group consisting of Li, Na, Ag, Cd and Zn, the element B is at least one element selected from the group consisting of Mg, Ca and Cu, and the element C is at least one element selected from the group consisting of Ge, Al and Ga.

When the above elements are selected as the elements A, B and C, it is easier to increase the light absorption coefficient α and/or keep the band gap Eg at a suitable range.

When multiple substitutional doping is carried out by using the elements A, B and C and a combination of the elements A, B and C is optimized, the light absorption coefficient α can be increased while the band gap Eg is kept in a suitable range.

Multiple substitutional doping is preferably such that at least two types of doping selected from the group consisting of the following doping are carried out.

(1) First doping by at least one element selected from the group consisting of (a) Zn@Cu, Cd@Cu, Mg@Cu, Ca@Cu and Sr@Cu and (b) Cu@Zn
(2) Second doping by at least one element selected from the group consisting of (a) Ag@Cu, Li@Cu, Na@Cu and K@Cu, (b) Mg@Zn, Ca@Zn and Sr@Zn, and (c) Al@Sn, Ga@Sn and Ge@Sn
(3) Third doping by Se@S

“X@Y” denotes the substitution of the Y site by the element X.

When a combination of the above doping is selected as multiple substitutional doping, the following advantages are obtained: (1) the corresponding site can be relatively easily substituted, (2) the light absorption coefficient α is increased and/or (3) the band gap Eg is more easily kept in a suitable range.

Multiple substitutional doping is particularly preferably Al@Sn+Se@S, Ga@Sn+Se@S, Ge@Sn+Se@S, Zn@Cu+Al@Sn, Zn@Cu+Ga@Sn, Ag@Cu+Se@S, Li@Cu+Se@S, Na@Cu+Se@S, K@Cu+Se@S, Mg@Cu+Al@Sn, Mg@Cu+Ga@Sn, Mg@Zn+Se@S, Ca@Cu+Al@Sn, Ca@Cu+Ga@Sn, Ca@Zn+Se@S, Sr@Cu+Al@Sn, Sr@Cu+Ga@Sn, Sr@Zn+Se@S, Cd@Cu+Al@Sn or Cd@Cu+Ga@Sn.

When one of the above combinations is selected as multiple substitutional doping, the following advantages are obtained:

(1) the corresponding site can be substituted relatively easily,
(2) the light absorption coefficient α is increased, and/or
(3) the band gap Eg is more easily kept in a suitable range advantageously.

Preferably, the main constituent elements of the compound semiconductor satisfy the following relationship (1′).

(Cu_{1-w}A_{w})₂₍₁₊ₐ₎Zn_{1+b}(Sn_{1-y}C_{y})_{1+c}S_{4(1+d)} (1′)

where −0.3≦a≦0.3, −0.3≦b≦0.3, ≦0.3≦c≦0.3, −0.3≦d≦0.3, 0≦w<0.5, 0≦y≦0.5 and 0<y+w.

The element A is at least one element selected from the group consisting of Zn and Cd.

The element C is at least one element selected from the group consisting of Al and Ga.

Out of the compound semiconductors represented by the formula (1′), a compound semiconductor which has been subjected to multiple substitutional doping such as Zn@Cu+Al@Sn, Zn@Cu+Ga@Sn, Cd@Cu+Al@Sn or Cd@Cu+Ga@Sn is preferred.

### [1.2. Crystal Structure]

It is said that the CZTS-based compound generally takes a kesterite structure, a stannite structure or a wurtzite-stannite structure. Since the kesterite structure out of these is the most stable thermodynamically, a CZTS-based compound obtained by an existing production process generally takes a kesterite structure. However, according to production conditions, part of the CZTS-based compound may have a stannite structure or a wurtzite-stannite structure.

This can be said of the CZTSX-based compound. In general, the CZTSX-based compound takes a kesterite structure but according to production conditions, part of the compound may have a stannite structure or a wurtzite-stannite structure.

The compound semiconductor of the present invention is preferably composed of a CZTSX-based compound phase having a kesterite structure alone but may contain a CZTSX-based compound phase having a stannite structure or a wurtzite-stannite structure. The compound semiconductor of the present invention may contain a phase (heterogeneous phase) except for the CZTSX-based compound phase having any one of these crystal structures and inevitable impurities. It is preferred that the heterogeneous phase and inevitable impurities which have an adverse effect on conversion efficiency should be as small as possible in quantity.

Examples of the heterogeneous phase include Cu₂(S,Se), Sn(S,Se)₂, Zn(S,Se), Sn(S,Se) and Cu(S,Se).

### [1.3. Band Gap Eg]

In the present invention, the term “band gap Eg” means an energy difference between the upper end of a valence band and the lower end of a conduction band. Dopants are roughly divided into dopants which have the function of increasing the band gap Eg and dopants which have the function of reducing the bad gap Eg. Therefore, when the types of the elements A to C and the amounts of the elements A to C and Se are optimized, the value of the band gap Eg of the compound semiconductor obtained by first principle calculation can be adjusted to a range of 1.2 to 1.6 eV.

When the single substitutional doping of the CZTS-based compound with the element X is carried out, the change rate kₓ (=dEg/dn) of the band gap Eg with respect to the amount nₓ of substitutional doping can be obtained by first principle calculation. Table 1 shows an example of kₓ obtained by first principle calculation.

Therefore, when the types of the elements A to C and the amounts of the elements A to C and Se are optimized to satisfy the following expression (2), the value of the band gap Eg of the compound semiconductor obtained by first principle calculation can be adjusted to a range of 1.2 to 1.6 eV.

1.2 (eV)≦1.49+Σnₓkₓ≦1.6 (eV) (2)

where nₓ is the concentration (at %) of the element X substituting each site (the element A, the element B, the element C or Se).

kₓ is the change rate (dEg/dn) of the band gap Eg with respect to the amount nₓ of substitutional doping of the element X.

TABLE 1

| Single subsitutional doping | k = dEg/dn |
|---|---|
| Li@Cu | 0.055 |
| Na@Cu | 0.045 |
| Ge@Sn | 0.043 |
| K@Cu | 0.033 |
| Al@Sn | 0.033 |
| Ca@Zn | 0.023 |
| Mg@Zn | 0.016 |
| Ga@Sn | 0.012 |
| Sr@Zn | 0.012 |
| Ag@Cu | 0.010 |
| Se@S | −0.011 |
| Zn@Cu | −0.068 |
| Mg@Cu | −0.050 |
| Ca@Cu | −0.030 |
| Sr@Cu | −0.022 |
| Cu@Zn | −0.037 |

### [1.4 Light Absorption Coefficient α]

The light absorption coefficient α of the CZTS-based compound obtained by first principle calculation is 1.42. When the CZTS-based compound is doped with a certain element X, the light absorption coefficient α obtained by first principle calculation can be made larger than 1.42.

However, when the light absorption coefficient α is increased by single substitutional doping, the band gap Eg may decrease, thereby reducing the conversion efficiency.

In contrast to this, when the multiple substitutional doping of the CZTS-based compound is carried out by using a dopant having the function of increasing the light absorption coefficient α and a dopant having the function of increasing the band gap Eg, the light absorption coefficient α obtained by first principle calculation can be made larger than 1.42 while the band gap Eg is kept in a suitable range.

The term “light absorption coefficient α” means a value evaluated by the following expression using a dielectric constants ∈ (E) calculated by the HSE method and solar-spectral intensity I(E).

α≡∫I(E)Im∈(E)dE/∫I(E)dE

Im∈ (E) is the imaginary part of a dielectric constant indicative of the excitation probability of an electron by light having energy E.

### [1.5. Application]

The compound semiconductor of the present invention is suitable for use as the light absorbing layer of a photovoltaic device.

### 2. Production Process of Compound Semiconductor

The compound semiconductor of the present invention is obtained by the following steps:

(a) manufacturing a precursor including a metal, sulfide, oxide or hydroxide containing Cu, Zn and Sn, and elements A to C; and
(b) reducing the precursor as required and sulfurizing and/or selenizing the precursor.

For instance, to form a compound semiconductor film, a precursor film containing constituent metal elements is formed on a substrate. The method of forming the precursor film is not particularly limited and various methods may be employed. To form the precursor film, sputtering method, vacuum deposition method, pulse laser deposition method (PLD), plating method, chemical bath deposition method (CBD), electrophoretic deposition method (EPD), chemical vapor deposition method (CVD), spray pyrolysis deposition method (SPD), screen printing method, spin coating method and nano-particle deposition method may be employed.

The sulfurization of the precursor is carried out by heating the precursor at a predetermined temperature in a sulfur vapor or hydrogen sulfide atmosphere. The optimal sulfurization temperature, which differs according to the composition of the precursor, is generally 550 to 580° C.

When the sulfurization temperature is optimized, or heating and crystallization are carried out in an inert atmosphere such as nitrogen, CZTSX having a predetermined crystal structure is obtained.

The selenization of the precursor is carried out by heating the precursor at a predetermined temperature in a selenium vapor or hydrogen selenide atmosphere. The optimum selenization temperature, which differs according to the composition of the precursor, is generally 300 to 600° C.

When the selenization temperature is optimized, or heating and crystallization are carried out in an inert atmosphere such as nitrogen, CZTSX having a predetermined crystal structure is obtained. [3. Effect of Compound Semiconductor]

To obtain high photovoltaic conversion efficiency, the band gap Eg needs to be in a suitable range and the light absorption coefficient α needs to be high. When at least one site out of the Cu site, the Zn site, the Sn site and the S site of the CZTS-based compound is substituted by a specific element, the light absorption coefficient α increases or the bad gap Eg increases.

In general, a dopant having the function of increasing the light absorption coefficient α tends to reduce the band gap Eg. For example, when the S site of CZTS is substituted by Se or the Zn site of CZTS is substituted by Cu, excitation probability becomes high, whereby high light absorption coefficient α is obtained but the band gap Eg becomes small. Therefore, when a dopant having the function of increasing the light absorption coefficient α is added alone, the band gap Eg goes out of a suitable range, whereby photovoltaic conversion efficiency may be lowered.

In contrast to this, when a dopant having the function of increasing the light absorption coefficient α and reducing the band gap Eg and a dopant having the function of increasing the band gap Eg (for example, Al, Ga and Ge at the Sn site) are added at the same time, the light absorption coefficient α increases while the band gap Eg is kept in a suitable range. Since these substitution elements are stable energetically, they are stable without changing by temperature or light.

### EXAMPLES

### Example 1

### 1. Calculation Method

The stable structures, doping formation energies, band gaps and dielectric constants of CZTS or CZTSe and compositions obtained by carrying out the substitutional doping thereof were calculated by first principle calculation program VASP (planar wave-PAW method using density functional formalism). Exchange potential GGA was used for the calculation of the stable structure. The accuracy of structural prediction was 1% or less.

The HSE method (Non-Patent Document 9) was used for the calculation of the band gap and the dielectric constant. Convergence was confirmed by using a screening parameter used for HSE calculation of 0.2, a planar cut-off of 350 eV, and a k point of 4×4×4−8×8×8. When known solar cell materials CIS, CISe, CGS and CGSe were evaluated, the prediction accuracy of the band gap of each of these compound semiconductors by the HSE method was 0.2 eV or less. A band gap of 1.49 eV (Non-Patent Document 10) and a band gap of 0.89 eV were obtained for CZTS and CZTSe, respectively.

### 2. Doping Formation Energy

Doping formation energy ΔH was evaluated for a CZTS or CZTSe super cell (64 atoms) including substitutional doping by various elements from the following equation.

ΔH=(E_{D}−E_{sc})−ΣΔn_{α}μ_{α}

where E_{D} is the total energy of a cell including doping, E_{sc} is the total energy of crystals without doping, Δn_{α} is the ratio of the number of missing elements a to the number of introduced elements α, and μ_{α} is the chemical potential of α.

The chemical potential changes according to process conditions. The chemical potential values of Cu, Zn, Sn and S were obtained from heat equilibrium conditions with a coexisting phase by the method described in Non-Patent Document 13. The chemical potential of another element was calculated from the phase equilibrium state with a phase shown in Table

2. As ΔH is smaller, doping becomes more stable. Particularly when ΔH is negative, self-doping can occur without providing external energy such as thermal excitation.

TABLE 2

| D.P. | Space group | D.P. | Space group | D.P. | Space group |
|---|---|---|---|---|---|
| Ag₂S | P2₁/C | Cu₂O | Pn-3m | SeS | Fm-3m |
| Al₂S₃ | P6₁, I4₁/amd, R-3c | ZnO₂ | Pa-3 | KS | P-62m |
| GaS | P6₃/mmc, R-3m | ZnO | P6₃mc | K₂S | Fm-3m |
| Ga₂S₃ | Cc | SnO | P4/nmm01 | K₂S₃ | Cmc2₁ |
| SiS₂ | Ibam, I-42d | SnO₂ | Pbcn | K₂S₅ | P2₁2₁2₁ |
| GeS | Pnma | SO₂ | gas | Li₂S | Fm-3m |
| GeS₂ | I-42d, Pc, P2₁/c | CuSe | P6₃/mmc | NaS | P6₃/mmc |
| Cu₃N | Pm-3m | Cu₃Se₂ | P-42₁m | NaS₂ | I-42d |
| Zn₃N₂ | Ia-3 | ZnSe₂ | Pa-3 | NA₂S₅ | Pnma |
| Sn₃N₄ | Fd-3m | ZnSe | F-43m | MgS | Fm-3m |
| SN | P2₁/c | ZnSe | P6₃mc | CaS | Fm-3m |
| S₂N | P4₂nm | SnSe | Fm-3m | SrS | Fm-3m |
| Sb₂S₃ | Pnma | SnSe | Pnma | SrS₂ | I4/mcm |
| Bi₂S₃ | Pnma | SnSe₂ | P-3m1 | SrS₃ | Aba2 |

* D.P.: Deposition phase

### 3. Evaluation of Amount of Substitutional Doping

The change rate dEg/dn of the band gap with respect to the amount nₓ of substitutional doping by element X was obtained by first principle calculation. Eg is a band gap. The change of the band gap by single substitutional doping is obtained from nₓ×dEg/dnₓ. The change of the band gap of a material which has been subjected to multiple substitutional doping is approximated by ΔEg=ΣdEg/dnₓ×nₓ.

Meanwhile, the upper limit of nₓ was obtained from conditions under which a band gap Eg of 1.2 to 1.6 eV suitable for solar cell materials was achieved.

### 4. Evaluation of Light Absorption Coefficient α

The light absorption coefficient α was calculated by the HSE method. Light absorption coefficient α of 1.42 was obtained for CZTS. It is judged that when it is larger than this, the solar cell material has the effect of improving conversion efficiency.

### 5. Results

### [5.1. Formation Energy]

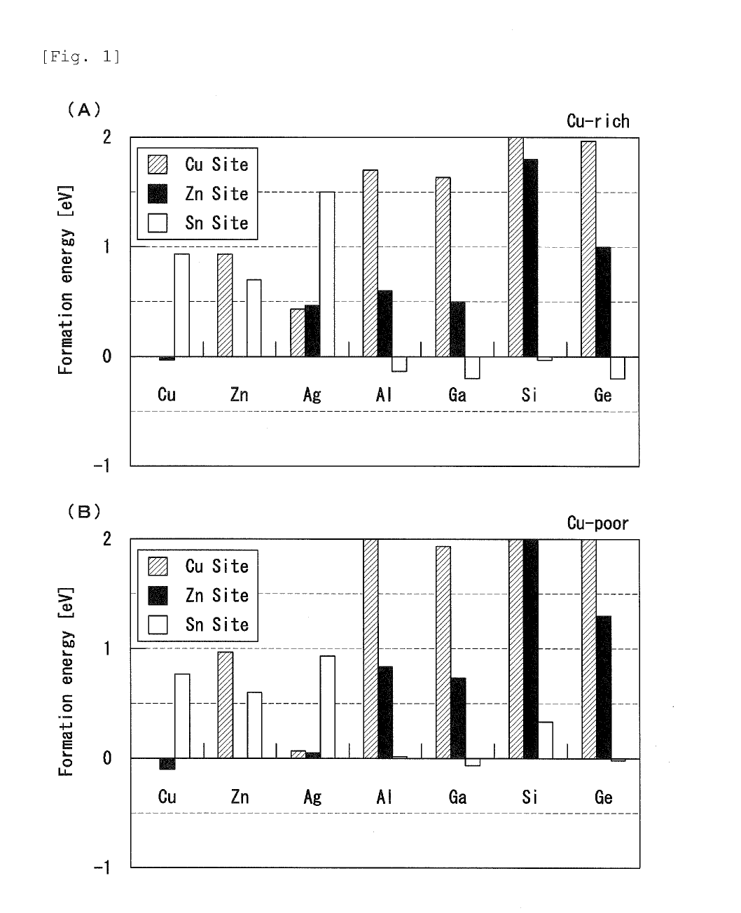

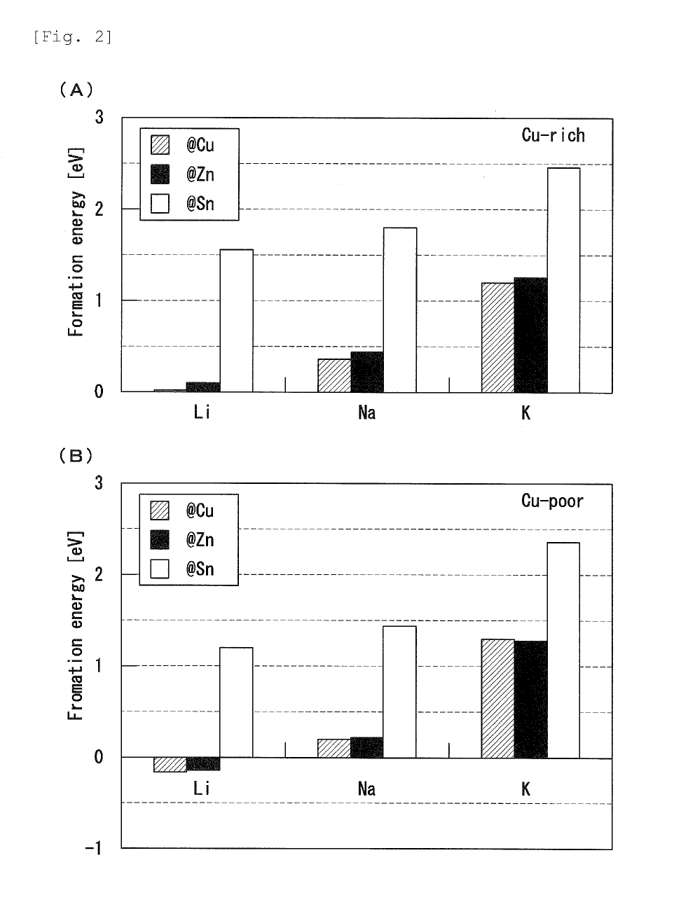

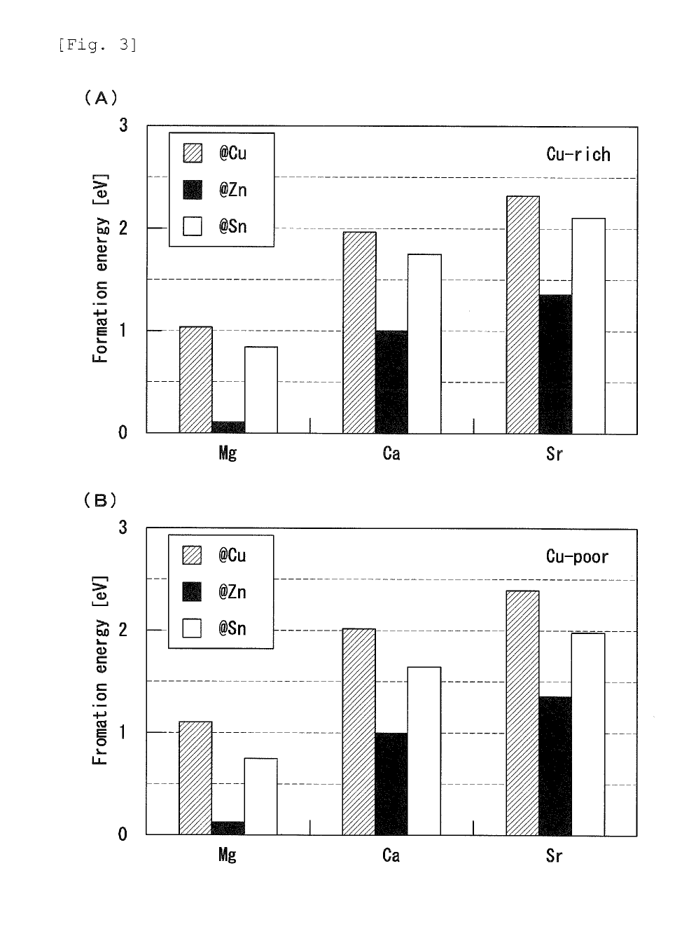

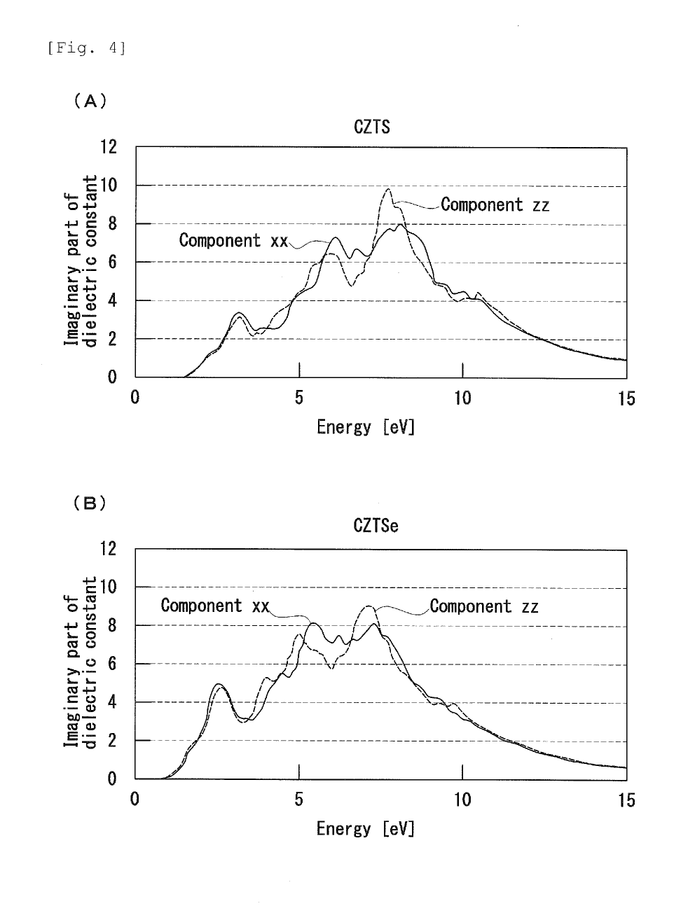

FIGS. 1A to 3B show the formation energy of each type of doping for CZTS. Results obtained (1) when the process condition was with excessive Cu and (2) the process condition was poor in Cu (Non-Patent Document 13) are shown. By assuming a formation energy for stable doping is 1.0 eV or less, the following candidates (group 1) for substitutional doping were obtained from the calculation results.

### Group 1:

Zn@Cu, Ag@Cu, Cu@Zn, Ag@Zn, Al@Zn, Ga@Zn, Cu@Sn, Ag@Sn, Zn@Sn, Al@Sn, Ga@Sn, Si@Sn, Ge@Sn, Se@S, Li@Cu, Na@Cu, Li@Zn, Na@Zn, Mg@Zn, Ca@Zn and Mg@Sn

The doping of the Sn site with Al, Ga, Si or Ge is much more stable than the doping of the Cu site or the Zn site. Similarly, the doping of the Zn site with Mg and the doping of the Zn site with Cu are more stable than the doping of other sites. In consideration of these, the following suitable candidates (group 2) were obtained out of the group 1.

### Group 2:

Zn@Cu, Ag@Cu, Cu@Zn, Ag@Zn, Zn@Sn, Al@Sn, Ga@Sn, Si@Sn, Ge@Sn, Se@S, Li@Cu, Na@Cu, Li@Zn, Na@Zn, Mg@Zn and Ca@Zn

### [5.2. Imaginary Part of Dielectric Constant]

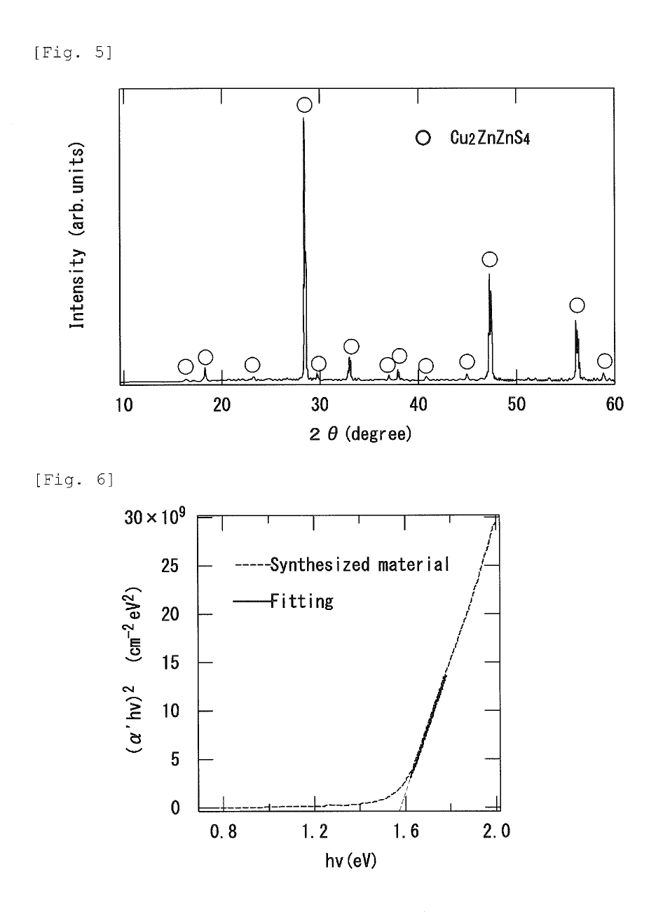

FIGS. 4A and 4B show the imaginary parts of the dielectric constants of CZTS and CZTSe obtained by calculation. A peak at around 2.5 eV indicates electron transition from the valence band to the conduction band. Since CZTSe has a larger dielectric constant than CZTS, it is understood that the substitution of S by Se is effective in order to obtain high absorption characteristics of light.

However, CZTS has a band gap of 1.49 eV which is a suitable value as a solar cell material whereas CZTSe has a small band gap of 0.89 eV.

Therefore, it is important to control the substitution amount of Se to a suitable value.

### [5.3. Single Substitutional Doping]

Table 3 shows the calculation results of single substitutional doping. In Table 3, “Eg” is a band gap when the amount of substitutional doping is n(at %), and “α” is a light absorption coefficient when the amount of substitutional doping is n(at %). “n(at %)@Eg=1.6 eV” is the amount n(at %) of the substitutional doping required to obtain a band gap of 1.6 eV calculated by using kₓ. The same can be said of “n(at %)@Eg=1.5 eV”.

As shown in Table 3, when Se is doped in an amount of 12.5 at %, the light absorption coefficient α of CZTS is improved from 1.42 of CZTS to 1.79. Meanwhile, the band gap is slightly reduced to 1.35 eV. However, this band gap is still in a suitable range as a solar cell material.

When the amount of Se is increased to 25 at %, α is improved to 2.34 and the band gap is reduced to 1.23 eV. When the amount of Se is increased more than that, the band gap becomes 1.2 eV or less, thereby deteriorating efficiency. In this case, the band gap can be adjusted to a suitable range of 1.2 to 1.6 eV by multiple substitutional doping for increasing the band gap.

The existence of elements (group 3) which increase the band gap by single substitutional doping and elements (group 4) which reduce the band gap out of the elements of group 2 was confirmed from Table 3.

### Group 3:

### Ag@Cu, Al@Sn, Ga@Sn, Ge@Sn, Li@Cu, Na@Cu, Mg@Zn and Ca@Zn

### Group 4:

### Zn@Cu, Cu@Zn and Se@S

Although the single substitutional doping of Cd@Cu was not calculated, it is understood from the calculated value and experimental result of multiple substitutional doping which will be described hereinafter that Cd@Cu is an element (element of group 4) which reduces the band gap.

For these forms of doping, the upper limit of the doping amount was evaluated based on the condition under which Eg was 1.2 to 1.6 eV. It was confirmed from the value of light absorption coefficient α that performance of Se@S (26 at % or less) was improved compared to CZTS.

TABLE 3

| Single | | | | | | | | | |
|---|---|---|---|---|---|---|---|---|---|
| substitutional | | | | | n(at %) | n(at %) | n(at %) | n(at %) | n(at %) |
| doping | Eg_(eV) | n(at %) | α | k = dEg/dn | @Eg = 1.2 eV | @Eg = 1.3 eV | @Eg = 1.4 eV | @Eg = 1.5 eV | @Eg = 1.6 eV |
| Li@Cu | 1.84 | 6.25 | 0.93 | 0.0549 | | | | 0.10 | 1.93 |
| Na@Cu | 1.78 | 6.25 | 1.04 | 0.0450 | | | | 0.13 | 2.35 |
| Ge@Sn | 1.76 | 6.25 | 1.09 | 0.0425 | | | | 0.13 | 2.49 |
| K@Cu | 1.70 | 6.25 | 1.26 | 0.0332 | | | | 0.17 | 3.18 |
| Al@Sn | 1.70 | 6.25 | 1.01 | 0.0329 | | | | 0.17 | 3.21 |
| Ca@Zn | 1.64 | 6.25 | 1.34 | 0.0233 | | | | 0.24 | 4.53 |
| Mg@Zn | 1.60 | 6.25 | 1.30 | 0.0161 | | | | 0.35 | 6.56 |
| Ga@Sn | 1.57 | 6.25 | 1.17 | 0.0125 | | | | 0.46 | 8.47 |
| Sr@Zn | 1.57 | 6.25 | 1.48 | 0.0116 | | | | 0.49 | 9.11 |
| Ag@Cu | 1.56 | 6.25 | 1.31 | 0.0104 | | | | 0.55 | 10.16 |
| Se@S(12.5 at %) | 1.35 | 12.50 | 1.79 | −0.0113 | 26.02 | 17.18 | 8.34 | | |
| Se@S(25.0 at %) | 1.23 | 25.00 | 2.34 | −0.0106 | 27.82 | 18.36 | 8.91 | | |
| Zn@Cu | | | | −0.0679 | 4.34 | 2.86 | 1.39 | | |
| Mg@Cu | | | | −0.0500 | 5.89 | 3.89 | 1.89 | | |
| Ca@Cu | | | | −0.0300 | 9.81 | 6.48 | 3.14 | | |
| Sr@Cu | | | | −0.0220 | 13.38 | 8.83 | 4.29 | | |
| Cu@Zn(½) | 1.26 | 6.25 | 1.83 | −0.0368 | 7.99 | 5.27 | 2.56 | | |
| CZTS | 1.49 | | 1.42 | | | | | | |

### [5.4. Multiple Substitutional Doping]

Table 4 shows the results of multiple substitutional doping. In Table 4, the doping amount except for Se@S is the same as “n” in Table 3. The doping amount of Cd@Cu is 12.5%.

The calculated value of the band gap perfectly agreed with a value (1.49+Σn*k) estimated by multiplying k=dE/dn of single substitutional doping with the amount “n” of doping and adding the obtained product for each type of doping. It was found from Table 4 that the band gap could be accurately estimated for arbitrary multiple substitutional doping from the calculated value (Table 3) of single substitutional doping. That is, the band gap can be adjusted to 1.2 to 1.6 eV at which the maximum efficiency is obtained by controlling the concentration of each doping element X so as to satisfy 1.2≦1.49+Σnₓkₓ≦1.6 by using the concentration nₓ (at %) and kₓ in Table 3.

As shown in Table 4, based on the condition that the light absorption coefficient α should be larger than that (α=1.42) of CZTS, a high-performance solar cell material was obtained by multiple substitutional doping such as Zn@Cu+Ga@Sn, Ag@Cu+Se@S, Mg@Zn+Se@S, Na@Cu+Se@S, Li@Cu+Se@S or Ca@Zn+Se@S.

Although the calculated value of Eg was less than 1.2 eV in the case of Cd@Zn+Al@Sn and Cd@Cu+Ga@Sn, α was equal to or higher than those of other examples. Therefore, it is expected that the band gap will be kept at 1.2 eV or more and the light absorption coefficient α will be increased according to the doping amount in these cases.

The results obtained from Cd@Cu+Al@Sn and Cd@Cu+Ga@Sn shown in Table 4 are based on the condition that the doping amount of Cd is 12.5%, and the band gaps at that time are 1.11 eV and 1.00 eV, respectively. When the doping amount is 0% (Cu₂ZnSnS₄), the band gap is 1.49 eV. Therefore, when the doping amounts of Cd are obtained from Eg by doping Cd@Cu+Al@Sn (6.25%) and Cd@Cu+Ga@Sn (6.25%) to achieve a band gap of 1.2 eV, they are 9.54% and 7.40%, respectively.

Consequently, it is considered that even when Cd is doped in an amount of up to 9.54% in the case of Cd@Cu+Al@Sn (6.25%) and up to 7.40% in the case of Cd@Cu+Ga@Sn (6.25%), the band gap is kept at 1.2 eV or more and the light absorption coefficient α can be increased.

TABLE 4

| Multiple Substitutional Doping | Eg (eV) | 1.49 + (Σ n*k) | α |
|---|---|---|---|
| Al@Sn + Se@S (12.5 at %) | 1.56 | (1.56) | 1.26 |
| Ga@Sn + Se@S (12.5 at %) | 1.42 | (1.43) | 1.47 |
| Ge@Sn + Se@S (12.5 at %) | 1.56 | (1.53) | 1.48 |
| Zn@Cu + Al@Sn | 1.27 | (1.28) | 1.55 |
| Zn@Cu + Ga@Sn | 1.16 | (1.15) | 1.78 |
| Ag@Gu + Se@S (12.5 at %) | 1.42 | (1.42) | 1.68 |
| Li@Cu + Se@S (25.0 at %) | 1.55 | (1.57) | 1.57 |
| Na@Cu + Se@S (25.0 at %) | 1.58 | (1.51) | 1.59 |
| K@Cu + Se@S (25.0 at %) | 1.52 | (1.44) | 1.78 |
| Mg@Cu + Al@Sn | 1.40 | (1.39) | 1.37 |
| Mg@Cu + Ga@Sn | 1.27 | (1.26) | 1.59 |
| Mg@Zn + Se@S (12.5 at %) | 1.45 | (1.45) | 1.64 |
| Ca@Cu + Al@Sn | 1.51 | (1.51) | 1.48 |
| Ca@Cu + Ga@Sn | 1.39 | (1.38) | 1.65 |
| Ca@Zn + Se@S (12.5 at %) | 1.45 | (1.50) | 1.70 |
| Sr@Cu + Al@Sn | 1.56 | (1.56) | 1.61 |
| Sr@Cu + Ga@Sn | 1.44 | (1.43) | 1.77 |
| Sr@Zn + Se@S (12.5 at %) | 1.50 | (1.43) | 1.49 |
| Cd@Cu + Al@Sn | 1.11 | — | 1.67 |
| Cd@Cu + Ga@Sn | 1.00 | — | 1.88 |

### Example 2

### 1. Manufacture of Sample

Raw materials (Cu₂S, Zn, SnS, S, Cd, Al, Ga) were weighed in a predetermined ratio and mixed together well in a mortar, and the resulting mixture was molded into a green compact. The green compact was encapsulated into a quartz tube in vacuum. Thereafter, it was reacted in a muffle furnace at 900° C. for 48 hours. The obtained sample was pulverized and sintered by a spark plasma sintering apparatus at 750° C. and 50 MPa for 5 minutes.

The X-ray diffraction pattern of the sample 1 (sample prepared by weighing Cu, Zn, Sn and S in a ratio of 2:1:1:4) agreed with a peak of Cu₂ZnSnS₄, and a heterogeneous phase peak was not observed (FIG. 5). Samples doped with various elements were based on the composition of sample 1.

### 2. Polishing of Surface of Sample

The surface of the sample was polished with the diamond abrasive (particle size of 1 mm) of Buhler AG to obtain a mirror surface. The dependence upon light energy E of the dielectric constant E of the sample having a mirror surface was measured. The spectroscopic ellipsometer (M2000-U) of J. A. Woollam Co., Ltd. was used as a measuring instrument.

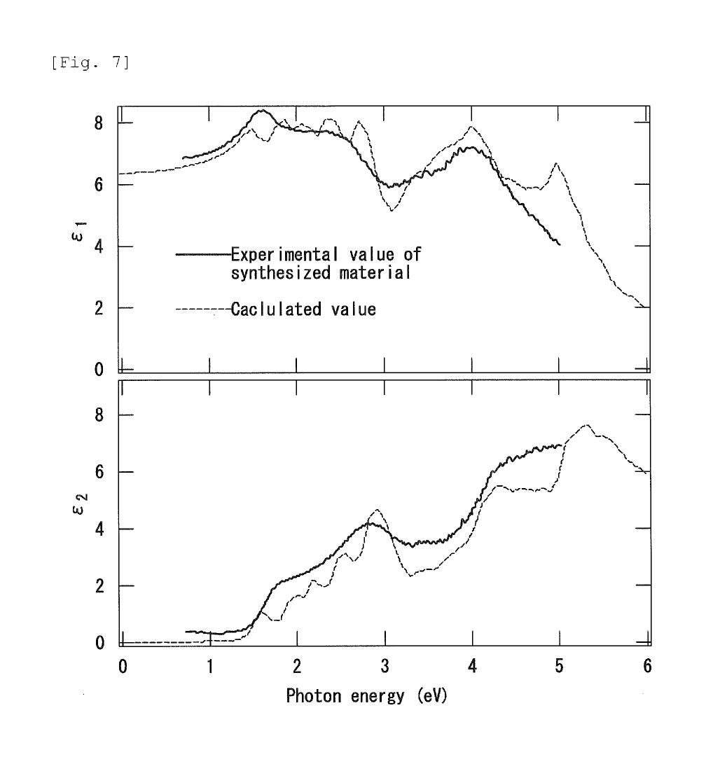

The dielectric constants ∈₁ and ∈₂ of the sample 1 perfectly agreed with the light energy dependence of the dielectric constant of Cu₂ZnSnS₄ obtained by electronic structure calculation (FIG. 6). Since the dielectric constant agreed with the electronic structure calculation result, it was judged that the surface could be fully polished, and all the samples were polished under the same conditions.

### 3. Evaluation of Band Gap of Synthesized Material

In the case of a direct transition semiconductor such as Cu₂ZnSnS₄, the band gap Eg is obtained from the light energy E dependence of absorption coefficient α′ (E−Eg∝(αE)²). The light energy E dependence of absorption coefficient α′ was obtained by means of the spectral ellipsometer (M2000-U) of J.A. Woollam Co., Ltd. It was found from the absorption coefficient α′ that the band gap Eg of the sample 1 was 1.58 eV (FIG. 7).

### 4. Evaluation of Solar Absorption Coefficient of Synthesized Material

The solar absorption coefficient α was evaluated from the following expression by using the dielectric constant ∈(E) and the spectral intensity I(E) of solar illumination.

α≡∫I(E)Im∈(E)/∫I(E)dE

where Im∈ (E) is the imaginary part ∈₂ (E) of dielectric constant indicative of the excitation probability of an electron by light having energy. The sample 1 had an α of 1.66. When α of the sample which has been doped is larger than this, it is judged that the doping has the effect of improving conversion efficiency.

### 5. Results

Table 5 shows the band gap Eg and the solar absorption coefficient α of the synthesized sample. The solar absorption coefficient α improved and the band gap fell within a range of 1.2 to 1.6 eV when the Cu site was doped with Zn and the Sn site was doped with Al at the same time. Similarly when the Cu site was doped with Zn and the Sn site was doped with Ga at the same time, the solar absorption coefficient α improved and the band gap Eg fell within a range of 1.2 to 1.6 eV.

When the results of the doping of Cu site by Zn and the doping of Cu site by Cd were compared with each other, there was almost no difference between them and the doping of the Cu site by Cd was also effective in increasing the solar absorption coefficient.

The excitation probability is increased by substituting part of the Cu site by Zn or Cd, thereby obtaining a high solar absorption coefficient. However, the band gap becomes small.

The reduction of the band gap causes the reduction of photovoltaic conversion efficiency. Then, when part of the Sn site is substituted by an element increasing the bang gap such as Al or Ga simultaneously with the substitution of the Cu site, a band gap at which the maximum efficiency of a solar cell material is obtained (1.2 to 1.6 eV) can be achieved.

TABLE 5

| Synthesized material | Band gap Eg (eV) | α |
|---|---|---|
| Sample 1 (Cu₂ZnSnS₄) | 1.58 | 1.66 |
| (Cu_{0.99}Zn_{0.01})₂Zn(Sn_{0.98}Al_{0.02}) S₄ | 1.45 | 1.89 |
| (Cu_{0.975} Zn_{0.025})₂Zn(Sn_{0.95}Al_{0.05}) S₄ | 1.41 | 2.10 |
| (Cu_{0.99}Cd_{0.01})₂Zn(Sn_{0.98}Al_{0.02}) S₄ | 1.46 | 1.88 |
| (Cu_{0.975}Cd_{0.025})₂Zn (Sn_{0.95}Al_{0.05}) S₄ | 1.39 | 2.24 |
| (Cu_{0.975}Zn_{0.025})₂Zn (Sn_{0.95}Ga_{0.05}) S₄ | 1.43 | 1.90 |
| (Cu_{0.975}Cd_{0.025})₂Zn (Sn_{0.95}Ga_{0.05}) S₄ | 1.43 | 1.91 |

* α: Solar absorption coefficient

### Reference Example 1

### 1. Manufacture of Sample

A solar cell was manufactured by the following procedure.

(1) An Mo back electrode layer (layer thickness of up to 1 μm) was formed on a soda lime glass (SLG) substrate by sputtering.

(2) A Cu—Ag—Zn—Sn—S precursor film was formed on the Mo back electrode layer by sputtering. Then, the precursor film was sulfurized at 550 to 580° C. and atmospheric pressure in a 20% H₂S+N₂ gas atmosphere for 3 hours to be converted into a CZTSX (X=Ag) light absorbing layer (layer thickness: 1 to 2 μm). The substitution amount of Ag was 0%, 10%, 25%, 50% or 100%.

(3) A CdS film was formed on the CZTSX film by CBD.
(4) A Ga:ZnO window layer (layer thickness of up to 400 nm) and a comb-like Al surface electrode layer (layer thickness of up to 0.6 μm) were formed in this order on the CdS film by sputtering.
(5) The effective light receiving area of the manufactured solar cell was about 0.16 cm².

### 2. Testing Method

### [2.1. Composition Analysis]

The composition of the CZTSX film was measured by ICP.

### [2.2. Characteristics of Solar Cell]

The I-V characteristics (short-circuit current density (J_{sc}), open circuit voltage (V_{oc}), fill factor (F.F.) and conversion efficiency (E_{ff})) of the manufactured solar cell were evaluated. A solar simulator was used for measurement. Pseudo-solar illumination having an air mass of 1.5 (AM1.5) was applied to the solar cell to start measurement right away, and the measurement was completed in about 20 sec.

The conversion efficiency (E_{ff}), open circuit voltage (V_{OC}), short-circuit current density (J_{SC}), fill factor (F.F.) and pseudo-solar illumination energy (Eₛᵤₙ) per unit area of the irradiated plane have the following relationship (a).

E_{ff}=V_{OC}×J_{SC}×F.F.÷Eₛᵤₙ (a)

### [2.3. X-Ray Diffraction]

The X-ray diffraction pattern of the CZTSX film was measured.

### 3. Results

### [3.1. Composition Analysis]

The obtained CZTSX film had an a′/(b′+c′) ratio of 0.9, a b′/c′ ratio of 1.2 and a d′/(a′+b′+c′) ratio of 1.5.

### [3.2. I-V Characteristics]

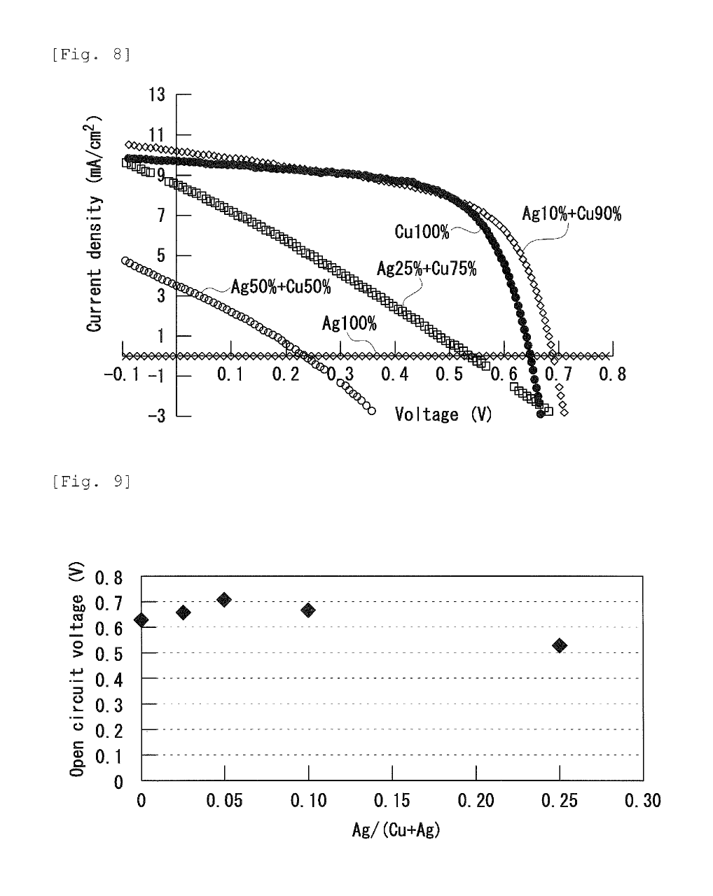

FIG. 8 shows the I-V characteristics of the solar cell. The following can be understood from FIG. 8.

(1) A solar cell including an Ag_{a′}Zn_{b′}Sn_{c′}S_{d′} film (an Ag 100% film) as a light absorbing layer did not generate power.
(2) A solar cell including a (Cu_{0.5}Ag_{0.5})_{a′}Zn_{b′}Sn_{c′}S_{d′} film (an Ag 50% film) as a light absorbing layer had lower V_{oc}, J_{sc} and F.F. than a solar cell including a Cu_{a′}Zn_{b′}Sn_{c′}S_{d′} film (a Cu 100% film).
(3) A solar cell including a (Cu_{0.75}Ag_{0.25})_{a′}Zn_{b′}Sn_{c′}S_{d′} film (an Ag 25% film) as a light absorbing layer had higher V_{oc} and J_{sc} than that including the Ag 50% film and values close to that including the Cu 100% film. However, F.F of the solar cell including the Ag 25% film was lower than that of the solar cell including the Cu 100% film.
(4) A solar cell including a (Cu_{0.9}Ag_{0.1})_{a′}Zn_{b′}Sn_{c′}S_{d′} film (an Ag 10% film) as a light absorbing layer had the same or higher J_{sc} and F. F. than that including the Cu 100% film as a light absorbing layer and higher V_{oc} than that including the Cu 100% film.

FIG. 9 shows the effect of improving V_{oc} by the addition of Ag. The following can be understood from FIG. 9.

(1) When 0<x≦0.15 in the (Cu₁₋ₓAgₓ)_{a′}Zn_{b′}Sn_{c′}Sn_{d′} film, the same or higher V_{oc} than the Cu 100% film is obtained.
(2) When 0.025≦x≦0.10 in the (Cu₁₋ₓAgₓ)_{a′}Zn_{b′}Sn_{c′}S_{d}′ film, a V_{oc} of 0.67 V or more is obtained.
(3) When 0.03≦x≦0.07 in the (Cu₁₋ₓ)_{a′}Zn_{b′}Zn_{b′}Sn_{c′}S_{d′} film, a V_{oc} of 0.69 V or more is obtained.
(4) When x is 0.05 in the (Cu₁₋ₓAgₓ)_{a′}Zn_{b′}Sn_{c′}S_{d′} film, the highest V_{oc} is obtained.

As one of the effects obtained by adding Ag, the improvement of V_{oc} can be expected. The improvement of V_{oc} could be confirmed by the comparison of I-V measurement results between when Ag was added and when Ad was not added.

V_{oc} of the solar cell is determined by the band gap, and as the band gap becomes wider, V_{oc} is improved. The improvement of V_{oc} by the addition of Ag was in good agreement with the calculated value that the k value of Ag@Cu was positive (Table 3).

### [3.3. X-ray Diffraction]

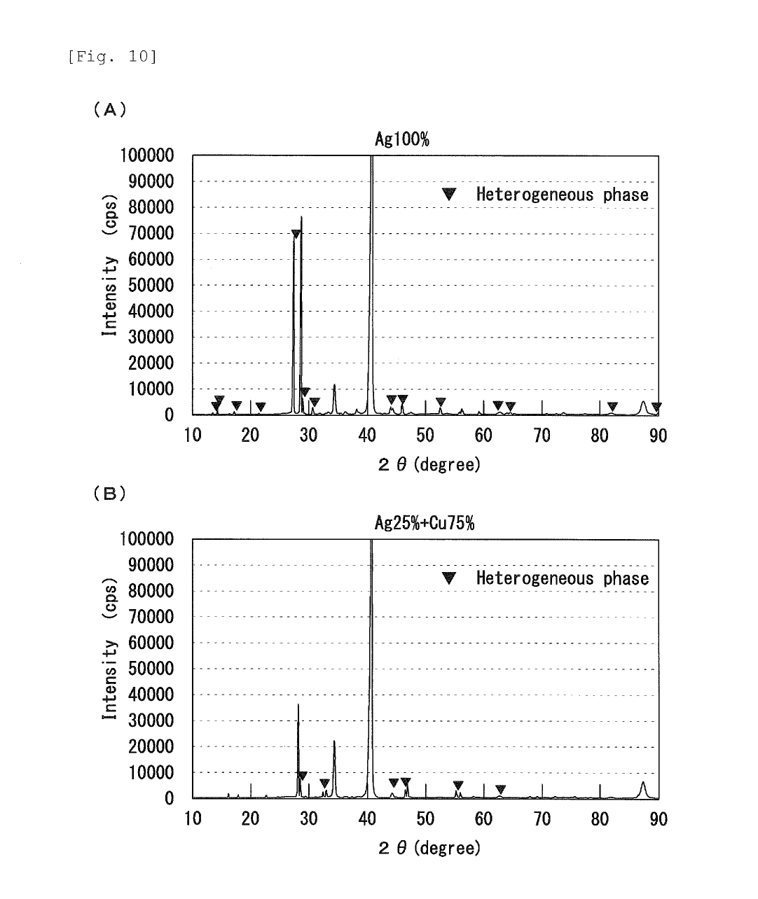

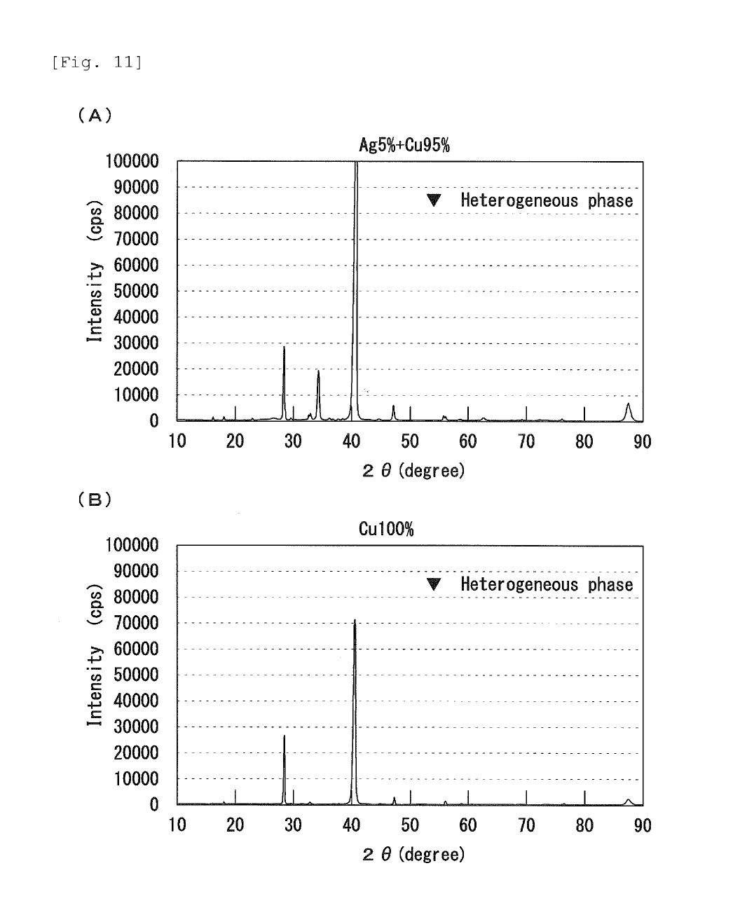

FIGS. 10A, 10B, 11A and 11B show the X-ray diffraction patterns of the (Cu₁₋ₓAgₓ)_{a′}Zn_{b′}Sn_{c′}S_{d′} film. It is understood from these figures that a peak different from that of CZTS was detected when x≧0.25 and the structure was changed.

While a preferred embodiment of the present invention has been described above in detail, it is to be understood that the present invention is not limited thereto and various changes and modifications may be made without departing from the spirit or scope of the invention.

The compound semiconductor of the present invention can be used as a light absorbing layer for thin-film solar cells, photoconductive cells, photodiodes, phototransistors and sensitized solar cells.

What is claimed is:

1. A compound semiconductor having the following constitution:
(1) the compound semiconductor contains main constituent elements (Cu, Zn, Sn, S, Se, element A, element B and element C) and inevitable impurities, and the main constituent elements satisfy the following relationship (1):
Cu_{1-w}A_{w})₂₍₁₊ₐ₎(Zn₁₋ₓBₓ)_{1+b}(Sn_{1-y}C_{y})_{1+c}(S_{1-z}Se_{z})_{4(1+d)} (1)
where −0.3≦a≦0.3, −0.3≦b≦0.3, −0.3≦c≦0.3, −0.3≦d≦0.3, 0≦w≦0.5, 0≦x<0.5, 0≦y<0.5, 0≦z≦0.5 and 0<x+y+z+w,
the element A is at least one element selected from the group consisting of Li, Na, K, Mg, Ca, Sr, Ag, Cd and Zn,
the element B is at least one element selected from the group consisting of Mg, Ca, Sr and Cu,
the element C is at least one element selected from the group consisting of Ge, Al and Ga, and
(i) a compound in which x=y=z=0 and the element A is Ag, (ii) a compound in which x=y=w=0, and (iii) a compound in which x=z=w=0 and the element C is Ga are excluded from the formula (1); and
(2) the compound semiconductor has a CZTSX-based compound phase as a main phase.

2. (canceled)

3. The compound semiconductor according to claim 1,
wherein the element A is at least one element selected from the group consisting of Li, Na, Ag, Cd and Zn,
the element B is at least one element selected from the group consisting of Mg, Ca and Cu, and
the element C is at least one element selected from the group consisting of Ge, Al and Ga.

4. The compound semiconductor according to claim 1, wherein multiple substitutional doping of at least two selected from the group consisting of
(1) first doping by at least one element selected from the group consisting of (a) Zn@Cu, Cd@Cu, Mg@Cu, Ca@Cu and Sr@Cu and (b) Cu@Zn,
(2) second doping by at least one element selected from the group consisting of (a)Ag@Cu, Li@Cu, Na@Cu and K@Cu, (b) Mg@Zn, Ca@Zn and Sr@Zn and (c) Al@Sn, Ga@Sn and Ge@Sn, and
(3) third doping by Se@S
is carried out (“X@Y” denotes the substitution of the Y site by the element X).

5. The compound semiconductor according to claim 4, wherein the multiple substitutional doping is Al@Sn+Se@S, Ga@Sn+Se@S, Ge@Sn+Se@S, Zn@Cu+Al@Sn, Ag@Cu+Se@S, Li@Cu+Se@S, Na@Cu+Se@S, K@Cu+Se@S, Mg@Cu+Al@Sn, Mg@Cu+Ga@Sn, Mg@Zn+Se@S, Ca@Cu+Al@Sn, Ca@Cu+Ga@Sn, Ca@Zn+Se@S, Sr@Cu+Al@Sn, Sr@Cu+Ga@Sn, Sr@Zn+Se@S, Cd@Cu+Al@Sn or Cd@Cu+Ga@Sn.

6. The compound semiconductor according to claim 1,
wherein the main constituent elements satisfy the following relationship (1′):
(Cu_{1-w}A_{w})₂₍₁₊ₐ₎Zn_{1+b}(Sn_{1-y}C_{y})_{1+c}S_{4(1+d)} (1′)
where −0.3≦a≦0.3, −0.3≦b≦0.3, −0.3≦c≦0.3, −0.3≦d≦0.3, 0≦w<0.5, 0≦y<0.5 and 0<y+w,
the element A is at least one element selected from the group consisting of Zn and Cd, and
the element C is at least one element selected from the group consisting of Al and Ga.

7. The compound semiconductor according to claim 6, wherein multiple substitutional doping of Zn@Cu+Al@Sn, Cd@Cu+Al@Sn or Cd@Cu+Ga@Sn is carried out.

8. The compound semiconductor according to claim 1, wherein a value of energy difference (band gap) between the upper end of a valence band and the lower end of a conduction band obtained by first principle calculation is 1.2 to 1.6 eV.

9. The compound semiconductor according to claim 1, wherein a value of energy difference (band gap) between the upper end of a valence band and the lower end of a conduction band obtained by first principle calculation satisfies the following relationship (2):
1.2 (eV) 1.49+Σnₓkₓ≦1.6 (eV) (2)
where nₓ is the concentration (at %) of the element X (the element A, the element B, the element C or Se) substituting each site, and kₓ is a change rate (dEg/dn) of the band gap Eg with respect to the amount nₓ of substitutional doping by the element X.

10. The compound semiconductor according to claim 1, wherein a light absorption coefficient α obtained by first principle calculation is larger than 1.42.
